(19) United States
(12) Patent Application Publication
(10) Pub. No.: US 2025/0239987 A1
(43) Pub. Date: Jul. 24, 2025

(54) ELECTROACOUSTIC RESONATOR WITH MODIFIED CHARGE TRAPPING REGION

(71) Applicant: RF360 Singapore Pte. Ltd., Singapore (SG)

(72) Inventors: Matthias KNAPP, Munich (DE); Constantin WALENTA, Stockdorf (DE); Guenter SCHEINBACHER, Baldham (DE); Simon SCHMIEDEKIND, München (DE)

(21) Appl. No.: 18/420,646

(22) Filed: Jan. 23, 2024

(51) Int. Cl. H03H 9/02; H03H 3/08; H03H 9/25

(52) U.S. Cl. CPC H03H 9/02952; H03H 3/08; H03H 9/25

(57) ABSTRACT

Aspects are provided for electroacoustic resonators with modified charge trapping regions. In one aspect, a device includes a substrate layer, a trap rich layer disposed on the substrate layer, the trap rich layer having a thickness less than or equal to 200 nanometers (nm), a dielectric layer disposed on the trap rich layer, a piezoelectric layer disposed on the dielectric layer, and an interdigital transducer formed in a metal layer disposed on the piezoelectric layer.

### TECHNICAL FIELD

The present disclosure relates generally to electronic communications. For example, aspects of the present disclosure relate to electroacoustic resonators, and in particular, to the use of an updated charge trapping layer (e.g., trap rich layer) to improve device performance.

### BACKGROUND

Electronic devices include traditional computing devices such as desktop computers, notebook computers, tablet computers, smartphones, wearable devices like a smartwatch, internet servers, and so forth. These various electronic devices provide information, entertainment, social interaction, security, safety, productivity, transportation, manufacturing, and other services to human users. These various electronic devices depend on wireless communications for many of their functions. Wireless communication systems and devices are widely deployed to provide various types of communication content such as voice, video, packet data, messaging, broadcast and so on.

Electronic devices may be capable of supporting communication with multiple users by sharing available communications resources (e.g., time, frequency, and power). Examples of communications protocols include code division multiple access (CDMA) systems, time division multiple access (TDMA) systems, frequency division multiple access (FDMA) systems, and orthogonal frequency division multiple access (OFDMA) systems, (e.g., a Long Term Evolution (LTE) system, or a New Radio (NR) system).

Wireless communication transceivers used in these electronic devices generally include multiple radio frequency (RF) filters for filtering a signal for a particular frequency or range of frequencies. Electroacoustic devices (e.g., “acoustic filters”) are used for filtering high-frequency (e.g., generally greater than 100 MHz) signals in many applications. Using a piezoelectric material as a vibrating medium, acoustic resonators operate by transforming an electrical signal wave that is propagating along an electrical conductor into an acoustic wave that is propagating via the piezoelectric material. The acoustic wave propagates at a velocity having a magnitude that is significantly less than that of the propagation velocity of the electromagnetic wave. Generally, the magnitude of the propagation velocity of a wave is proportional to a size of a wavelength of the wave. Consequently, after conversion of an electrical signal into an acoustic signal, the wavelength of the acoustic signal wave is significantly smaller than the wavelength of the electrical signal wave. The resulting smaller wavelength of the acoustic signal enables filtering to be performed using a smaller filter device. This permits acoustic resonators to be used in electronic devices having size constraints, such as the electronic devices enumerated above (e.g., particularly including portable electronic devices such as cellular phones).

### SUMMARY

Disclosed are systems, apparatuses, methods, and computer-readable media for electroacoustic resonators with a modified thin charge trapping region.

According to at least one example, a device is provided. The device comprises a resonator configured for resonance associated with a resonance wavelength, the resonator comprising: a conductive substrate layer, a trap rich layer disposed on the conductive substrate layer, the trap rich layer having a thickness less than or equal to 0.125 times the resonance wavelength, a dielectric layer disposed on the trap rich layer, a piezoelectric layer formed on the dielectric layer, and an interdigital transducer formed in a metal layer disposed on the piezoelectric layer.

According to another example, a method is provided. The method includes depositing a trap rich layer on a high resistance silicon substrate, wherein the trap rich layer is deposited to a thickness of less than or equal to 200 nanometers (nm), forming a dielectric layer on the trap rich layer, forming a piezoelectric layer on the dielectric layer, and forming an interdigital transducer on the piezoelectric layer.

According to another example, a device is provided. The device comprises a substrate layer, a trap rich layer disposed on the substrate layer, the trap rich layer having a thickness less than or equal to 200 nanometers (nm), a dielectric layer disposed on the trap rich layer, a piezoelectric layer disposed on the dielectric layer, and an interdigital transducer formed in a metal layer disposed on the piezoelectric layer.

Some such aspects are configured where the thickness of the trap rich layer is greater than or equal to 10 nm.

Some such aspects are configured where the trap rich layer comprises Aluminum Nitride.

Some such aspects are configured where the trap rich layer comprises Si3N4.

Some such aspects are configured where the trap rich layer comprises Al2O3.

Some such aspects are configured where the dielectric layer comprises SiO2.

Some such aspects further comprise a SiON layer disposed on the dielectric layer.

Some such aspects are configured where the substrate layer comprises polysilicon.

Some such aspects are configured where the substrate layer comprises a low cost high resistance silicon.

Some such aspects are configured where the thickness of the trap rich layer is selected to reduce out-of-band spurious modes while limiting the thickness of the trap rich layer.

Some such aspects are configured where the interdigital transducer comprises: a first busbar, a second busbar, and a first plurality of electrode fingers extending from the first busbar toward the second busbar and a second plurality of electrode fingers extending from the second busbar toward the first busbar in an interdigitated configuration with the first plurality of electrode fingers.

In some aspects, one or more of the apparatuses described herein is, is part of, and/or includes a mobile device (e.g., a mobile telephone and/or mobile handset and/or so-called “smartphone” or other mobile device), an extended reality (XR) device (e.g., a virtual reality (VR) device, an augmented reality (AR) device, or a mixed reality (MR) device), a head-mounted device (HMD) device, a vehicle or a computing system, device, or component of a vehicle, a wearable device (e.g., a network-connected watch or other wearable device), a wireless communication device, a camera, a personal computer, a laptop computer, a server computer, another device, or a combination thereof.

This summary is not intended to identify key or essential features of the claimed subject matter, nor is it intended to be used in isolation to determine the scope of the claimed subject matter. The subject matter should be understood by reference to appropriate portions of the entire specification of this patent, any or all drawings, and each claim.

The foregoing, together with other features and aspects, will become more apparent upon referring to the following specification, claims, and accompanying drawings.

### BRIEF DESCRIPTION OF DRAWINGS

FIG. 1A is a diagram of a perspective view of an example of an electroacoustic resonator.

FIG. 1B is a diagram of a side view of the electroacoustic resonator of FIG. 1A.

FIG. 2A is a diagram of a top view of an example of an electrode structure of an example electroacoustic resonator.

FIG. 2B is a diagram of a top view of an example of an electrode structure of an example electroacoustic resonator.

FIG. 3A is a diagram of a perspective view of another example of an electroacoustic resonator.

FIG. 3B is a diagram of a side view of the electroacoustic resonator of FIG. 3A.

FIG. 4 is a diagram of a view of an example electrode structure of an interdigital transducer (IDT) that can be used in a device with SAW resonators having a modified charge trapping region in accordance with aspects described herein.

FIG. 5 is a diagram of a resonator material stack including a thin trap rich layer in accordance with aspects described herein.

FIG. 6 is a diagram of aspects of a resonator material stack illustrating trap rich layer operation in accordance with aspects described herein.

FIG. 7A is a performance chart illustrating performance differences between an example thick polysilicon trap rich layer and a thin AlN trap rich layer in accordance with some aspects described herein.

FIG. 7B is a performance chart illustrating performance differences between an example thick polysilicon trap rich layer and a thin AlN trap rich layer in accordance with some aspects described herein.

FIG. 8A is a performance chart illustrating performance differences between trap rich layers in accordance with some aspects described herein.

FIG. 8B is a performance chart illustrating performance differences between trap rich layers in accordance with some aspects described herein.

FIG. 9 is a flowchart illustrating a method of operation of the disclosed electroacoustic devices, in accordance with examples described herein.

FIG. 10 is a schematic representation of an example filter that may employ the disclosed electroacoustic device, in accordance with examples described herein.

FIG. 11 is a functional block diagram of at least a portion of an example of a simplified wireless transceiver circuit in which the disclosed electroacoustic device described herein may be employed, in accordance with examples described herein.

FIG. 12 is a diagram of an environment that includes an electronic device that includes a wireless transceiver, such as the transceiver circuit of FIG. 11, in accordance with examples described herein.

### DETAILED DESCRIPTION

The detailed description set forth below in connection with the appended drawings is intended as a description of example implementations and is not intended to represent the only implementations in which the invention may be practiced. The detailed description includes specific details for the purpose of describing aspects of devices (e.g., surface acoustic wave (SAW) devices) in a configuration with a material stack including a thin charge trapping layer also referred to as a trap rich layer.

Electroacoustic devices (e.g., “acoustic filters”) can be used to filter high-frequency (e.g., generally greater than 100 MHZ) signals in many applications. An electroacoustic filter is tuned to pass certain frequencies (e.g., frequencies within its passband) and attenuate other frequencies (e.g., frequencies that are outside of its passband). Using a piezoelectric material as a vibrating medium in a transducer, the acoustic filter operates by transforming an electrical signal wave that is propagating along an electrical conductor into an acoustic wave (e.g., an acoustic signal wave) that forms across the piezoelectric material. The acoustic wave is then converted back into an electrical filtered signal. The cellular communication market, in particular, uses such electroacoustic devices. Within the cellular market, the market for wearable devices is growing at a very high rate. Aspects described herein can provide an improvement to such wearable devices, where very light and small devices with very high efficiency are prioritized over devices consuming higher power.

Given the value of space and reduced size for wireless communication devices, elements within such devices are designed to be as close as possible while maintaining acceptable performance. As electroacoustic resonators are positioned in close proximity, coupling between devices can occur, reducing device performance. Adding additional space between devices to limit coupling is not a preferred solution, as this increases device size. Additionally, material thickness and material type can impact parasitic coupling, cost, and space usage, impacting overall device performance.

Aspects described herein include resonators having a thin trap rich region that can provide an improvement over prior resonator stack structures with thicker trap rich regions by providing acceptable coupling performance while enabling lower cost stack structures and materials. Aspects described herein provide an unexpected benefit by achieving acceptable performance using materials with thin trap rich layers, when prior trap rich layer materials show degraded performance at reduced thicknesses. Thus, aspects described herein enable usage in carrier aggregation applications due to the improved electrical and acoustical performance. In addition, in some aspects, lower resistivity carrier substrates are used due to improved electrical characteristics.

For example, in some aspects, a thin Aluminum Nitride (AlN) layer can be used as a trap rich layer with a thickness between 10 and 200 nanometers (nm), compared with prior trap rich layers with thicknesses in the approximately 500 to 2500 nm range. Such a thin AlN layer operating as a trap rich layer can allow fabrication of the AlN trap rich layer on less costly HR-silicon when compared with costly engineered silicon substrate layers. Additionally, the deposition process for the thin AlN trap rich layer can be performed with greater thickness control and lower cost than prior trap rich layer fabrication (e.g., using thicker AlN layers or thicker layers of other material as the trap rich layer).

The additional control using trap rich layer deposition can additionally enable more specific design trade-offs between thickness and suppression of out-of-band spurious modes that the trap rich layer is designed to suppress, including in thin trap rich layers fabricated from other materials than AlN.

Various aspects of the present disclosure will be described with respect to the figures.

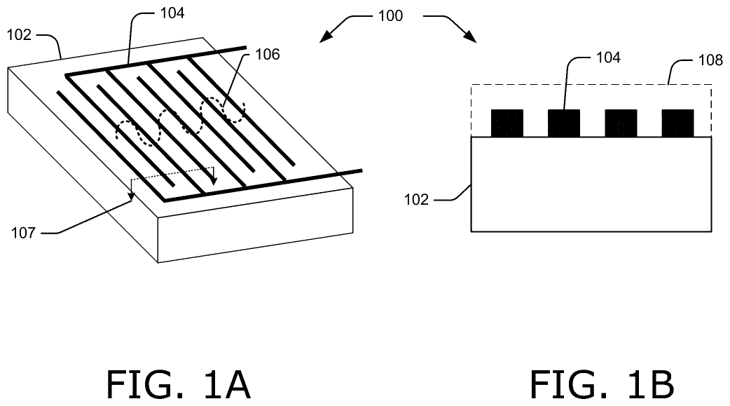

FIG. 1A is a diagram of a perspective view of an example of an electroacoustic transducer 100. The electroacoustic transducer 100 may be configured as, or be a portion of, a SAW resonator. In certain descriptions herein, the electroacoustic transducer 100 may be referred to as a SAW resonator. The electroacoustic transducer 100 includes an electrode structure 104, that may be referred to as an interdigital transducer (IDT), on the surface of a piezoelectric material 102. The electrode structure 104 generally includes first and second comb shaped electrode structures (conductive and generally metallic) with electrode fingers extending from two busbars towards each other arranged in an interlocking manner in between two busbars (e.g., arranged in an interdigitated manner). An electrical signal excited in the electrode structure 104 (e.g., applying an AC voltage) is transformed into an acoustic wave 106 that propagates in a particular direction via the piezoelectric material 102. The acoustic wave 106 is transformed back into an electrical signal and provided as an output. In many applications, the piezoelectric material 102 has a particular crystal orientation such that when the electrode structure 104 is arranged relative to the crystal orientation of the piezoelectric material 102, the acoustic wave mainly propagates in a direction perpendicular to the direction of the fingers (e.g., parallel to the busbars).

FIG. 1B is a diagram of a side view of the electroacoustic transducer 100 of FIG. 1A, along a cross-section 107 shown in FIG. 1A. The electroacoustic transducer 100 is illustrated by a simplified layer stack including a piezoelectric material 102 with an electrode structure 104 disposed on the piezoelectric material 102. The electrode structure 104 is conductive and generally formed from metallic materials. The piezoelectric material may be formed from a variety of materials such as quartz, lithium tantalate (LiTaO3), lithium niobate (LiNbO3), doped variants of these, or other piezoelectric materials. It should be appreciated that more complicated layer stacks (e.g., four (4) layers, six (6) layers, etc.), including layers of various materials, may be possible within the stack. For example, optionally, a temperature compensation layer 108 (denoted by the dashed lines) may be disposed above the electrode structure 104. The piezoelectric material 102 may be extended with multiple interconnected electrode structures disposed thereon to form a multi-resonator filter or to provide multiple filters. While not illustrated, when provided as an integrated circuit component, a cap layer may be provided over the electrode structure 104. The cap layer is applied so that a cavity is formed between the electrode structure 104 and an under surface of the cap layer. Electrical vias or bumps that allow the component to be electrically connected to connections on a substrate (e.g., via flip-chip or other techniques) may also be included.

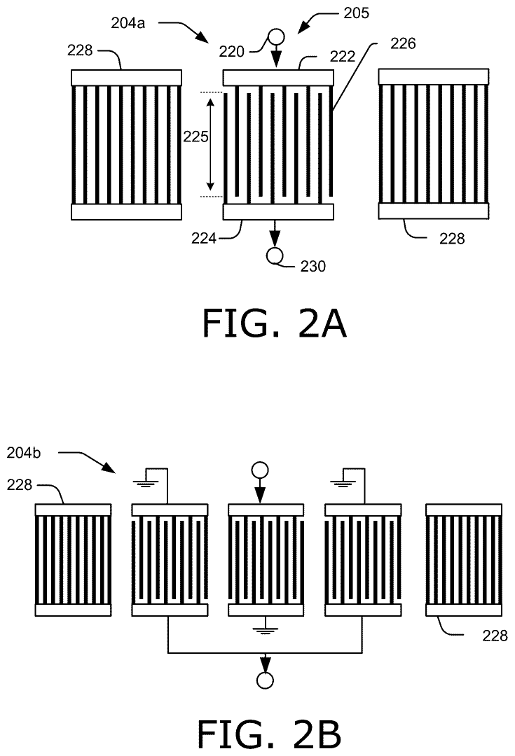

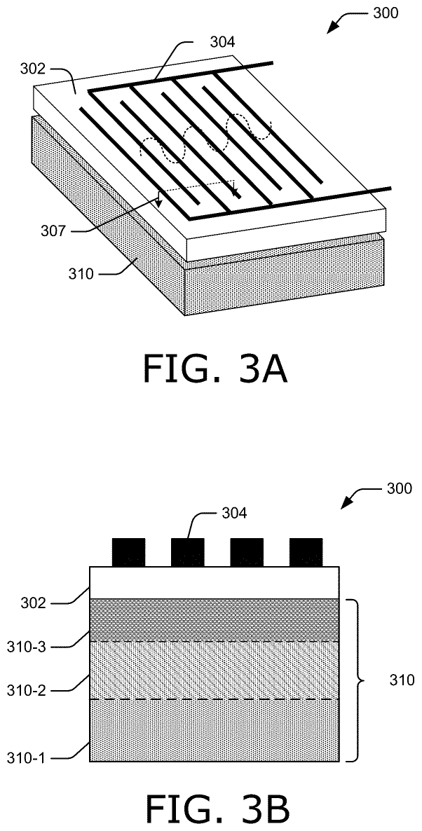

FIG. 2A is a diagram of a top view of an example of an electrode structure 204a of the electroacoustic transducer 100 configured with two reflectors 228 in a non-DMS configuration. FIG. 2A generally illustrates a one-port configuration. The electrode structure 204a has an IDT 205 that includes a first busbar 222 (e.g., first conductive segment or rail) electrically connected to a first terminal 220 and a second busbar 224 (e.g., second conductive segment or rail) spaced from the first busbar 222 and connected to a second terminal 230. A plurality of conductive fingers 226 are connected to either the first busbar 222 or the second busbar 224 in an interdigitated manner. Fingers 226 connected to the first busbar 222 extend towards the second busbar 224 but do not connect to the second busbar 224 so that there is a small gap between the ends of these fingers 226 and the second busbar 224. Likewise, fingers 226 connected to the second busbar 224 extend towards the first busbar 222 but do not connect to the first busbar 222 so that there is a small gap between the ends of these fingers 226 and the first busbar 222.

In the direction along a shared line parallel to the busbars 222 and 224, there is an overlap region including a central region where a portion of one finger overlaps with a portion of an adjacent finger (as illustrated by the central region 225). The central region 225 including the overlap may be referred to as the aperture, track, or active region where electric fields are produced between fingers 226 to cause an acoustic wave to propagate in the piezoelectric material 102. The periodicity of the fingers 226 is referred to as the pitch of the IDT. The pitch may be indicated in various ways. For example, in certain aspects, the pitch may correspond to a magnitude of a distance between fingers in the central region 225. The distance may be defined, for example, as the distance between center points of each of the fingers (and may be generally measured between a right (or left) edge of one finger and the right (or left) edge of an adjacent finger when the fingers have uniform thickness). As described herein, a “higher” pitch refers to sections of an IDT where electrode fingers have greater distances between adjacent electrode fingers, and a “lower” pitch refers to sections of an IDT where electrode fingers have lower distances between adjacent electrode fingers. In certain aspects, an average of distances between adjacent fingers may be used for the pitch. Having sections of an IDT with electrode fingers having a given pitch characteristic different from pitch characterizations of other sections of an IDT allows for selection or control of the signals (e.g., waves) that propagate through the IDT. The frequency at which the piezoelectric material vibrates is a self-resonance (also called a “main-resonance”) frequency of the electrode structure 204a. The frequency is determined at least in part by the pitch of the IDT 205 and other properties of the electroacoustic transducer 100.

In some examples, the pitch characteristics of sections of an IDT can be a constant pitch, where the pitch does not vary significantly over the IDT section (e.g., variances are within manufacturing tolerances, and are designed for a constant average pitch). In other examples, pitch characteristics of an IDT section can include a “chirped” pitch, where the pitch varies in a predefined way over the IDT section. For example, a chirped pitch can include an IDT section where the pitch is designed to change linearly across the IDT section, such that the pitch at one end of the IDT section is at a first value, the pitch at an opposite end of the IDT section is at a second value, and the pitch (e.g., the distance between electrode fingers) changes linearly between the two ends of the IDT section. In other examples, other non-linear variations in pitch value across an IDT section can be used. By combining IDT sections with different pitch characteristics (e.g., a constant pitch at a first value and a constant pitch at a second value, or a constant pitch at a first value in one IDT section and a chirped pitch across a second IDT section), the resonator characteristics can be designed for a given performance as described herein.

The IDT 205 is arranged between two reflectors 228 which reflect the acoustic wave back towards the IDT 205 for the conversion of the acoustic wave into an electrical signal via the IDT 205 in the configuration shown and to prevent losses (e.g., confine and prevent escaping acoustic waves). Each reflector 228 has two busbars along shared lines with corresponding busbars for the IDT 205 and a grating structure of conductive fingers that each connect to both busbars. The pitch of the reflector may be similar to or the same as the pitch of the IDT 205 to reflect acoustic waves in the resonant frequency range. But many configurations are possible.

When converted back to an electrical signal, the measured admittance or reactance between both terminals (i.e. the first terminal 220 and the second terminal 230) serves as the signal for the electroacoustic transducer 100.

FIG. 2B is a diagram of a top view of another example of an electrode structure 204b of an electroacoustic device. In this case, the electrode structure 204b includes a central IDT along with reflectors 228 connected as illustrated. The electrode structure 204b is provided to illustrate the variety of electrode structures and connections for structures that can be used in accordance with aspects described herein.

It should be appreciated that while a certain number of fingers 226 are illustrated, the number of actual fingers and lengths and width of the fingers 226 and busbars may be different in an actual implementation. Such parameters depend on the particular application and desired frequency of the filter. In addition, a SAW filter may include multiple interconnected electrode structures each including multiple IDTs to achieve a desired passband (e.g., multiple interconnected resonators or IDTs to form a desired filter transfer function).

FIG. 3A is a diagram of a perspective view of another example of an electroacoustic device 300. The electroacoustic device 300 (e.g., that may be configured as or be a part of a SAW resonator) is similar to the electroacoustic transducer 100 of FIG. 1A, but has a different layer stack. In particular, the electroacoustic device 300 includes a thin piezoelectric material 302 that is provided on a substrate 310 (e.g., silicon). Based on the type of piezoelectric material 302 used (e.g., typically having higher coupling factors relative to the electroacoustic transducer 100 of FIG. 1A) and a controlled thickness of the piezoelectric material 302, the particular acoustic wave modes excited may be slightly different than those in the electroacoustic transducer 100 of FIG. 1A. Based on the design (thicknesses of the layers, and selection of materials, etc.), the electroacoustic device 300 may have a higher Q-factor as compared to the electroacoustic transducer 100 of FIG. 1A. The piezoelectric material 302, for example, may be Lithium tantalate (LiTa03) or some doped variant. Another example of a piezoelectric material 302 for FIG. 3A may be Lithium Niobate (LiNbO3). In general, the substrate 310 may be substantially thicker than the piezoelectric material 302 (e.g., potentially on the order of 50 to 100 times thicker as one example—or more). The substrate 310 may include other layers as 310-1, 310-2, and 310-3 (or other layers may be included between the substrate 310 and the piezoelectric material 302).

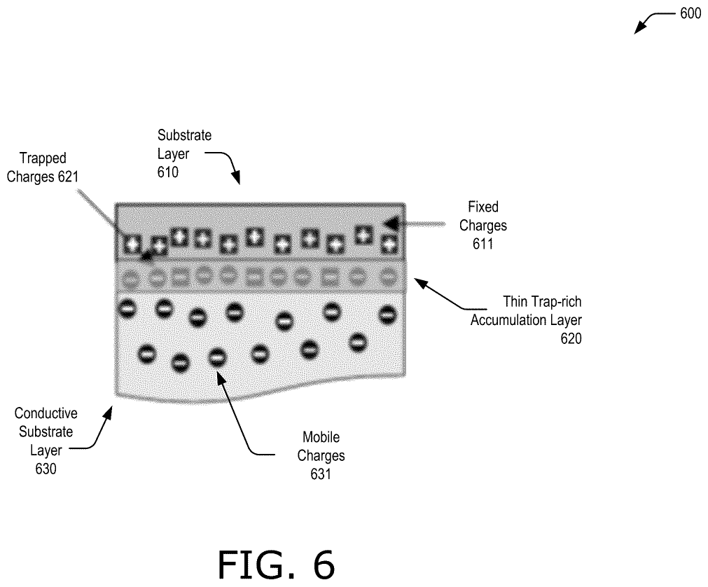

FIG. 3B is a diagram of a side view of the electroacoustic device 300 of FIG. 3A showing an example of a layer stack (along a cross-section 307) including a trap rich layer 310-2. As described herein, prior device structures include a trap rich layer to suppress parasitic resonances. Such resonances can particularly be caused by the use of certain materials which have parasitic surface conduction characteristics, as described in additional detail below with respect to FIG. 6. Prior systems address the parasitic resonance issue with higher cost substrate materials (e.g., engineered polycrystalline silicon), and the use of a dedicated thickness of this material (e.g., 500 nm or more) to reduce the number of charges contributing to parasitic surface conduction and/or increase the number of holes or traps available to stop the conductive layer charges from participating in parasitic surface conduction. Aspects described herein include material layers that provide an unexpectedly higher number of traps at thinner material levels, allowing the use of a thinner trap rich layer with substrate materials having a greater number of charges, resulting in reduced parasitic surface conduction with a thinner trap rich layer.

In the aspect shown in FIG. 3B, the substrate 310 may include sublayers such as a substrate sublayer 310-1 (e.g., of silicon) that may have a higher resistance (e.g., relative to the other layers-high resistivity layer). The substrate 310 may further include a trap rich layer 310-2 (e.g., dielectric films with a high sound velocity). The substrate 310 may further include a compensation layer (e.g., silicon dioxide (SiO2) or another dielectric material) that may provide temperature compensation and other properties. These sub-layers may be considered part of the substrate 310 or their own separate layers. A relatively thin piezoelectric material 302 is provided on the substrate 310 with a particular thickness for providing a particular acoustic wave mode (e.g., as compared to the electroacoustic transducer 100 of FIG. 1A where the thickness of the piezoelectric material 102 may not be a significant design parameter beyond a certain thickness and may be generally thicker as compared to the piezoelectric material 302 of the electroacoustic device 300 of FIGS. 3A and 3B). The electrode structure 304 is positioned above the piezoelectric material 302. In addition, in some aspects, there may be one or more layers (not shown) possible above the electrode structure 304 (e.g., such as a thin passivation layer).

Based on the type of piezoelectric material, the thickness, and the overall layer stack, the electromechanical coupling to the electrode structure 304 and acoustic velocities within the piezoelectric material in different regions of the electrode structure 304 may differ between different types of electroacoustic devices such as between the electroacoustic transducer 100 of FIG. 1A and the electroacoustic device 300 of FIGS. 3A and 3B.

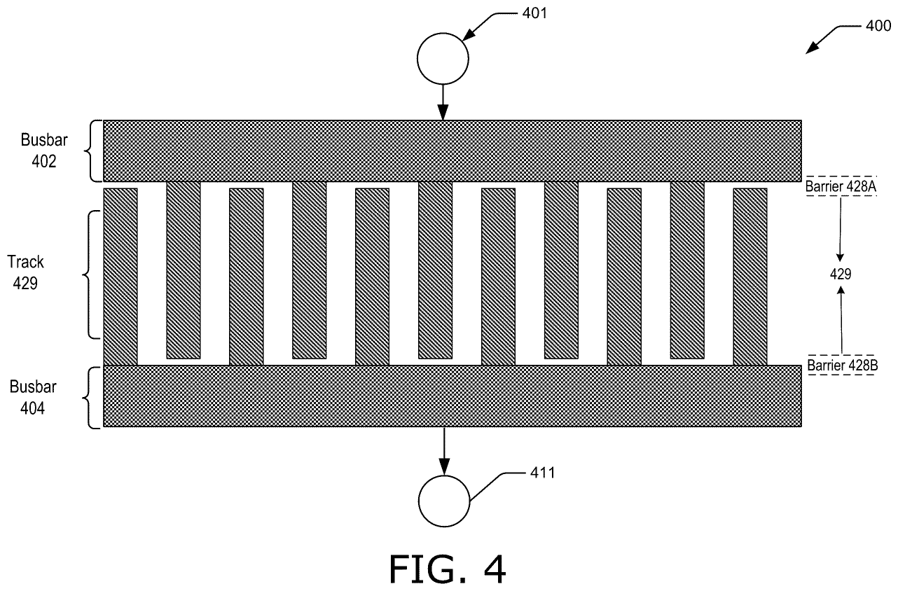

FIG. 4 is a diagram of a view of an example electrode structure 400 of an interdigital transducer (IDT) that can be used in a SAW resonator in accordance with aspects described herein. Just as above, the electrode structure 400 may be referred to as an IDT that can be fabricated on the surface of a piezoelectric material as part of the resonator. The electrode structure 400 includes first and second comb shaped electrodes. The comb teeth are within track 429, and supported by busbar 402 on one side and busbar 404 on the other side, with barriers 428A, 428B separating the track 429 from the busbars 402, 404. An electrical signal excited across the resonator by an electrical signal at input node 401 is transformed into an acoustic wave that propagates within the resonator, particularly within the track 429. The acoustic wave is transformed back into an electrical signal at the output node 411. The outer reflectors (e.g., reflectors 228, not shown in FIG. 4) will have a similar configuration, but without the barriers 428A, 428B, so that each finger of the reflectors couples across the track region to connect with both busbars.

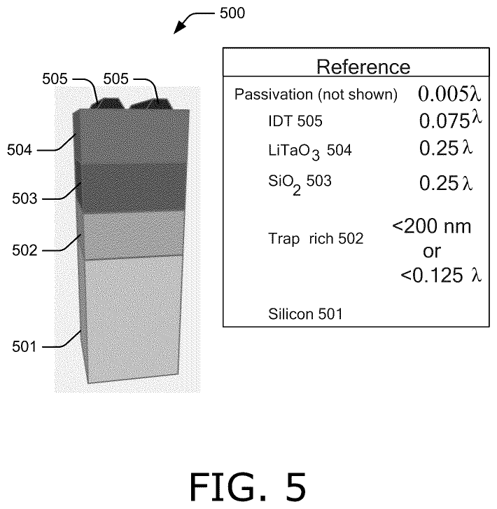

FIG. 5 is a diagram of a side view of a layer stack of an electroacoustic device 500. In particular, the electroacoustic device 500 is a SAW resonator having a resonator stack including a thin trap rich layer in accordance with aspects described herein. The plurality of layers in the resonator stack include a piezoelectric thin film layer (PL) 504, a compensating layer (CL) 503, a substrate (SU) 501, and a trap rich layer 502. The electroacoustic device 500 also comprises an electrode structure layer (EL) 505 (e.g., a metallization layer) located on top of the piezoelectric thin film layer 504. The device can further include a passivation layer (not shown) over the piezoelectric layer 504 and the electrode structure layer 505. For the electroacoustic device 500, the piezoelectric thin film layer 504 can, in some aspects, comprise lithium tantalate (LiTaO₃). In other aspects, other piezoelectric materials can be used. FIG. 5 also includes a table containing exemplary thicknesses of the layers of the electroacoustic device 500 relative to the wavelength (λ) of resonance of the electroacoustic device 500. The table additionally indicates that the trap rich layer is a thin layer having a thickness less than 200 nm, or less than approximately 0.125λ.

In various aspects, the material (e.g., crystal material) and cut of the piezoelectric thin film layer 504 may be selected such that performance parameters of the electroacoustic device 500, such as k2 quality and TCF of the main mode, meet specific device criteria. In one or more examples, the piezoelectric thin film layer 504 comprises lithium tantalate or lithium niobate with a particularly selected Euler angles for a given device performance. In one or more examples, the piezoelectric thin film layer 504 comprises a thickness x, where 0.1λ<x<0.6λ, and where λ is the wavelength of the acoustic main mode within the piezoelectric thin film layer 504 of the electroacoustic device 500. Similarly, the passivation layer can have a thickness of approximately 0.005λ, the IDT metallization layer 505 can have a thickness of approximately 0.075λ, the trap rich layer 502 can have a thickness between approximately 0.01λ and 0.125λ, or approximately between 10 nm and 200 nm, and the compensation layer can have a thickness of approximately 0.25λ, or a thickness y, where 0.05λ<y<0.5λ. In other aspects, layers other than the trap rich layer 502 can have other thicknesses. As described in more detail below, while polysilicon is a known material for trap rich layers operating at thicknesses greater than 200 nanometers (nm), and typically at thicknesses at or above 500 nm, aspects described herein include alternate materials for the trap rich layer 502, such as AlN, Si3N4, and Al2O3. Such materials, when used in the trap rich layer 502, show an unexpected benefit of maintaining performance effectiveness at thinner trap rich layer implementations below 200 nm or less than approximately 0.125λ, where polysilicon at such thicknesses suffers from a significant performance degredation when implemented as the trap rich layer 502 at such thicknesses.

The electrode structure layer 505 of the disclosed electroacoustic device 500 may comprise a conductive material. For example, the electrode structure layer 505 may include a layered structure comprising aluminum (Al) as the main component of the layered structure, and with a thickness b, where 0.05λ<b<0.25λ. (e.g., the thickness b is greater than or equal to 0.05 times the resonance wavelength, and less than or equal to 0.25 times the resonance wavelength). In one or more examples, the electrode structure layer 505 may comprise a layer structure comprising aluminum and having a layer thickness of 150 nm. In other examples, the electrode structure layer 505 may be a “heavy electrode” to reduce the velocity of the electroacoustic device 500. For these examples, the electrode structure layer 505 may comprise a copper (Cu)-based electrode system having one or more layers, or may comprise a single “heavy layer” comprising tungsten (W), molybdenum (Mo), titanium (Ti), and/or platinum (Pt).

In one or more examples, one or more dielectric passivation layers may be applied to the top of the electrode structure layer 505. As one example, each dielectric passivation layer may have a thickness d, where 0.0025λ<d<0.2λ. A dielectric passivation layer may comprise silicon nitride, silicon dioxide, silicon oxynitride (SiON), and/or aluminum oxide (Al₂O₃). In one or more examples, a dielectric passivation layer may comprise silicon nitride with a thickness of 10 nm.

FIG. 6 is a diagram of aspects of a resonator material stack 600 illustrating trap rich layer operation in accordance with aspects described herein. The resonator material stack 600 of FIG. 6 includes a substrate layer 630, a thin trap rich accumulation layer 620, and a substrate layer 610. These can, for example, be similar to layers 310-1, 310-2, and 310-3 as well as layers 501, 502, and 503 above. Additional layers, including a piezoelectric layer and an IDT metallization layer are not shown in FIG. 6, but are a part of resonator devices in accordance with aspects described herein as detailed and illustrated above.

As further illustrated, the substrate layer 610 includes fixed charges 611, and the substrate layer 630 includes mobile charges 631. When the substrate layer 630 is formed of HR-silicon, and the substrate layer 610 is formed of SiO₂, the magnitude of mobile charges 631 leads to parasitic surface conduction in connection with the fixed charges 611 of the substrate layer. This parasitic surface conduction results in losses due to electrical crosstalk. The presence of the trap rich accumulation layer 620 generates trapped charges 621 from the mobile charges 631, and reduces the impact of this electrical crosstalk, improving the performance of a resonator device.

As indicated above, prior implementations of trap rich accumulation layers used materials with a thickness of approximately 0.25λ, or greater than 500 nm, to reduce parasitic surface conduction. Polysilicon, in particular, when used as a trap rich layer, loses effectiveness in the reduction of parasitic surface conduction below 500 nm, due to the lack of sufficient trap structures in the material at reduced thickness to deal with the interactions between the fixed charges 611 of the substrate layer 610 and the mobile charges 631 of the substrate layer 630. Prior systems have been structured either using thicker layers of a trap rich layer with lower cost material such as HR-silicon as the substrate layer 630, using slightly thinner layers of material in a trap rich layer with a higher cost material such as engineered silicon, or with a design to tolerate performance reduction due to electrical crosstalk.

Review of trap rich layer performance of materials including polysilicon, Aluminum Nitride (AlN), Si3N4, and Al2O3 have identified that while polysilicon loses effectiveness as a trap rich layer material below 200 nm for the example layer stacks described above with respect to FIG. 5, AlN, Si3N4, and Al2O3 maintain performance effectiveness at thinner trap rich layer implementations. When extrapolating from the performance of polysilicon at thinner trap layer implementations, this performance of AlN, Si3N4, and Al2O3 is an unexpected result.

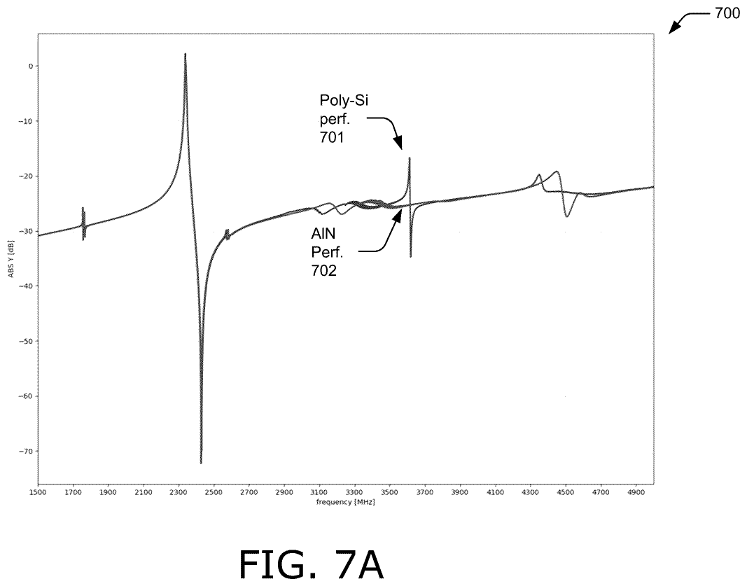

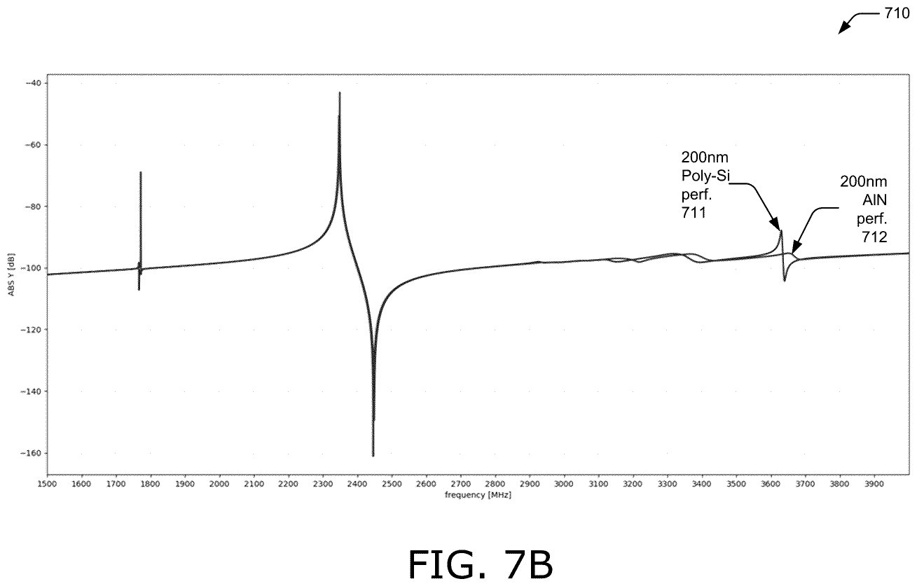

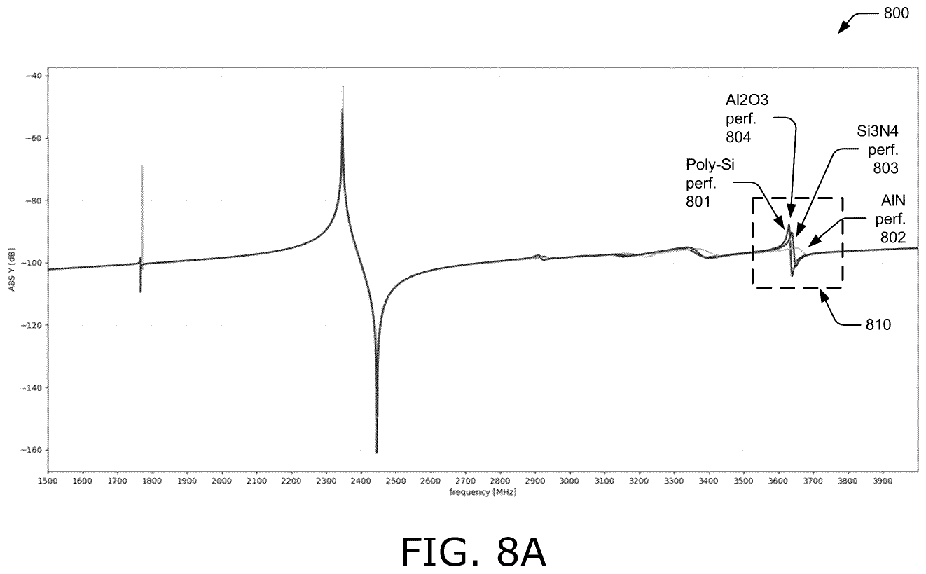

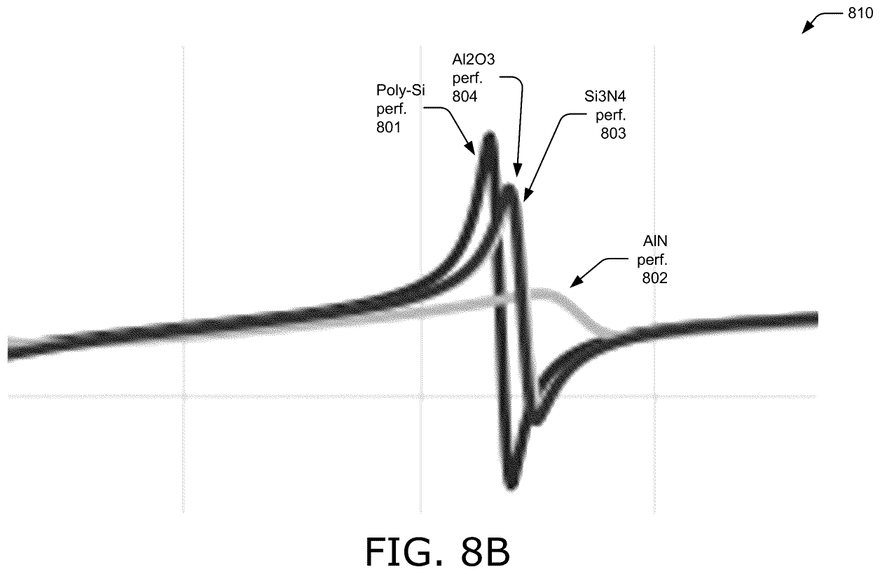

FIG. 7A is a performance chart 700 illustrating performance differences between an example thin polysilicon trap rich layer and a thin AlN trap rich layer in accordance with some aspects described herein. As indicated above, polysilicon is a standard material for trap rich layer implementations above 500 nm thicknesses. FIGS. 7A, 7B, 8A, and 8B are charts of admittance magnitude values on the y axis versus frequency on the x axis. In FIG. 7A, chart 700 is for polysilicon performance 701 and AlN performance 702 at thin trap rich layer implementations. The polysilicon performance 701 includes resonance spikes that result in significant performance reduction, while the AlN performance 702, while subject to passband ripples in out-of-band frequencies, does not include the significant performance degradation from the out-of-band spike seen in the polysilicon performance 701.

FIG. 7B includes a performance chart 710 similar to the performance chart 700. The performance chart 710 of FIG. 7B illustrates performance differences between 200 nanometer layers of polysilicon and AlN, when used as trap rich layers. The performance chart 710 includes 200 nm polysilicon performance 711 and 200 nm AlN performance. Just as shown in the performance chart 700, the AlN performance 712 does not include the significant performance degradation from the out-of-band spike seen in the 200 nm polysilicon performance 711.

FIG. 8A includes a performance chart 800 that illustrates example performance of four different trap rich layer materials. The performance chart includes polysilicon performance 801, AlN performance 802, Si3N4 performance 803, and Al₂O₃ performance 804. FIG. 8A illustrates an area 810 which is shown in greater detail in FIG. 8B.

FIG. 8B includes an enlarged image of the area 810 from the performance chart 800 of FIG. 8A. Al illustrated, the Al2O3 performance 804 and the Si₃N₄ performance 803 are nearly identical, and the AlN performance 802 does not include the resonance spikes seen in Si₃N₄ performance 803, polysilicon performance 801, and Al₂O₃ performance 804.

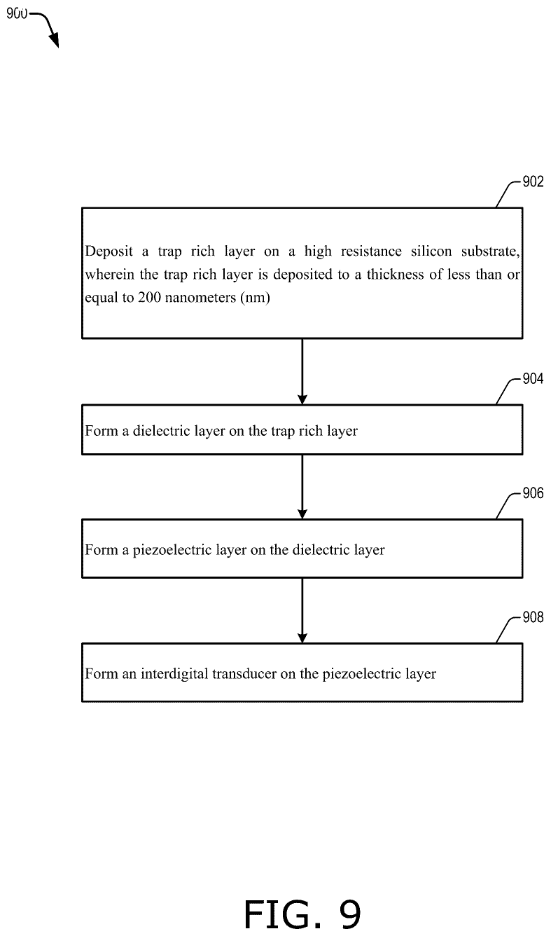

FIG. 9 is a flow diagram illustrating an example method 900 performed by an apparatus comprising a resonator in accordance with aspects described herein. The method 900 is described in the form of a set of blocks that specify operations that can be performed. However, operations are not necessarily limited to the order shown in FIG. 9 or described herein, for the operations may be implemented in alternative orders or in fully or partially overlapping manners. Also, more, fewer, and/or different operations may be implemented to perform the method 900, or an alternative process. In some aspects, the method 900 can be performed by a device comprising circuitry configured for operations of the method 900. In some aspects, control circuitry or one or more processors of the device can be configured to perform the operations. In some aspects, the method 900 can be implemented as instructions in a non-transitory computer readable storage medium that, when executed by one or more processors of the device, cause the device to perform operations of the method 900.

At block 902, the method 900 includes depositing a trap rich layer on a high resistance silicon substrate, wherein the trap rich layer is deposited to a thickness of less than or equal to 200 nanometers (nm). In some aspects, the trap rich layer is deposited to a thickness greater than or equal to 10 nm.

At block 904, the method 900 includes forming a dielectric layer on the trap rich layer. At block 906, the method 900 includes forming a piezoelectric layer on the dielectric layer. At block 908, the method 900 includes forming an interdigital transducer on the piezoelectric layer.

As described herein, in some aspects, the trap rich layer comprises Aluminum Nitride, and performance of AlN at thicknesses between 10 and 200 nm (inclusive) can provide performance sufficient for many applications while providing space and fabrication benefits.

Additionally, in some aspects, the trap rich layer comprises Si3N4 or Al₂O₃. In other aspects, the method 900 can be modified in accordance with any device described herein, or can be modified for fabrication of multiple devices or combined devices using repeated, intervening, or combined operations in accordance with the description of any device described herein.

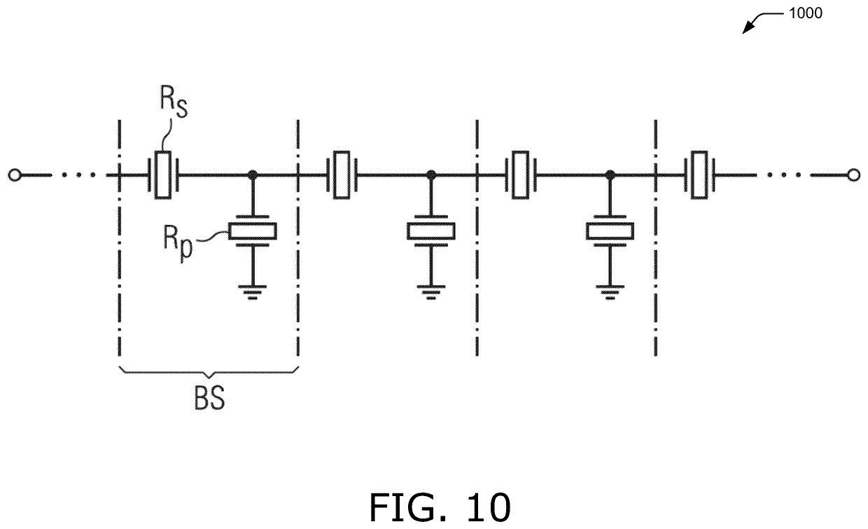

FIG. 10 is a schematic representation of an example filter 1000 that may employ multiple resonators on a shared piezoelectric surface, including SAW resonators with a modified charge trapping region in accordance with aspects described herein. The filter 1000 comprises a ladder-type arrangement of acoustic SAW resonators Rs, Rp (where Rs are series resonators and Rp are parallel resonators).

The ladder-type structure of the filter 1000 comprises a plurality of basic sections. Each basic section comprises at least one series resonator Rs and at least one parallel resonator Rp. The basic sections may be connected together in series in a number of basic sections that is necessary to achieve a desired selectivity. Series resonators Rs that belong to neighbored basic sections may be combined to a common series resonator Rs, and parallel resonators Rp may also be combined if they are directly neighbored and belonging to different basic sections. One basic section provides a basic filter. More basic sections can be added to provide for sufficient selectivity associated with a particular resonator used in the section.

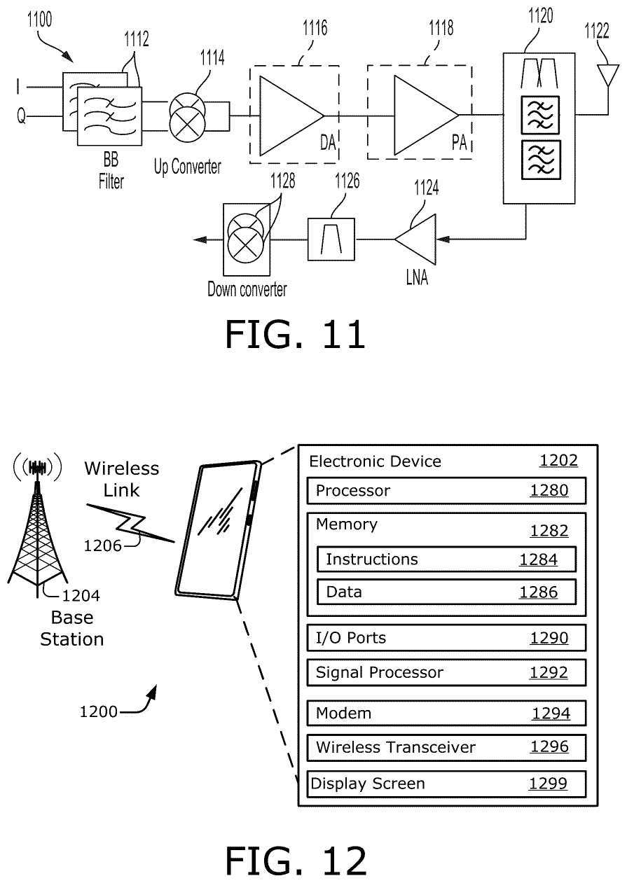

FIG. 11 is a functional block diagram of at least a portion of an example of a simplified wireless transceiver circuit 1100 in which resonators on a shared piezoelectric surface including SAW resonators with a modified charge trapping region in accordance with aspects described herein may be employed. The transceiver circuit 1100 is configured to receive signals/information for transmission (shown as I and Q values) which is provided to one or more base band filters 1112. The filtered output is provided to one or more mixers 1114. The output from the one or more mixers 1114 is provided to a driver amplifier 1116 whose output is provided to a power amplifier 1118 to produce an amplified signal for transmission. The amplified signal is output to the antenna 1122 through one or more filters 1120 (e.g., duplexers if used as a frequency division duplex transceiver or other filters). The one or more filters 1120 may include the disclosed DMS resonator. The antenna 1122 may be used for both wirelessly transmitting and receiving data. The transceiver circuit 1100 includes a receive path through the one or more filters 1120 to be provided to a low noise amplifier (LNA) 1124 and a further filter 1126 and then down-converted from the receive frequency to a baseband frequency through one or more mixer circuits 1128 before the signal is further processed (e.g., provided to an analog digital converter and then demodulated or otherwise processed in the digital domain). There may be separate filters for the receive circuit (e.g., may have a separate antenna or have separate receive filters) that may be implemented using the disclosed resonators including SAW resonators with a modified charge trapping region in accordance with aspects described herein.

FIG. 12 is a diagram of an environment 1200 that includes an electronic device 1202 that includes a wireless transceiver 1296, such as the transceiver circuit 1100 of FIG. 11. In some aspects, the electronic device 1202 includes a display screen 1299 that can be used to display information associated with data transmitted via wireless link 1206 and processed using components of electronic device 1202 described below. Other aspects of an electronic device in accordance with aspects described herein using a low phase delay filter for multi-band communication can be configured without a display screen. In the environment 1200, the electronic device 1202 communicates with a base station 1204 through a wireless link 1206. As shown, the electronic device 1202 is depicted as a smart phone. However, the electronic device 1202 may be implemented as any suitable computing or other electronic device, such as a cellular base station, broadband router, access point, cellular or mobile phone, gaming device, navigation device, media device, laptop computer, desktop computer, tablet computer, server computer, network-attached storage (NAS) device, smart appliance, an automobile including a vehicle-based communication system, Internet of Things (IoT) device, sensor or security device, asset tracker, and so forth.

The base station 1204 communicates with the electronic device 1202 via the wireless link 1206, which may be implemented as any suitable type of wireless link. Although depicted as a base station tower of a cellular radio network, the base station 1204 may represent or be implemented as another device, such as a satellite, terrestrial broadcast tower, access point, peer to peer device, mesh network node, fiber optic line, another electronic device generally as described above, and so forth. Hence, the electronic device 1202 may communicate with the base station 1204 or another device via a wired connection, a wireless connection, or a combination thereof. The wireless link 1206 can include a downlink of data or control information communicated from the base station 1204 to the electronic device 1202 and an uplink of other data or control information communicated from the electronic device 1202 to the base station 1204. The wireless link 1206 may be implemented using any suitable communication protocol or standard, such as 3rd Generation Partnership Project Long-Term Evolution (3GPP LTE, 3GPP NR 5G), IEEE 802.11, IEEE 802.16, Bluetooth™, and so forth.

The electronic device 1202 includes a processor 1280 and a memory 1282. The memory 1282 may be or form a portion of a computer readable storage medium. The processor 1280 may include any type of processor, such as an application processor or a multi-core processor, that is configured to execute processor-executable instructions (e.g., code) stored by the memory 1282. The memory 1282 may include any suitable type of data storage media, such as volatile memory (e.g., random access memory (RAM)), non-volatile memory (e.g., Flash memory), optical media, magnetic media (e.g., disk or tape), and so forth. In the context of the disclosure, the memory 1282 is implemented to store instructions 1284, data 1286, and other information of the electronic device 1202, and thus when configured as or part of a computer readable storage medium, the memory 1282 does not include transitory propagating signals or carrier waves.

The electronic device 1202 may also include input/output ports 1290. The I/O ports 1290 enable data exchanges or interaction with other devices, networks, or users or between components of the device.

The electronic device 1202 may further include a signal processor (SP) 1292 (e.g., such as a digital signal processor (DSP)). The signal processor 1292 may function similar to the processor and may be capable of executing instructions and/or processing information in conjunction with the memory 1282.

For communication purposes, the electronic device 1202 also includes a modem 1294, a wireless transceiver 1296, and an antenna (not shown). The wireless transceiver 1296 provides connectivity to respective networks and other electronic devices connected therewith using radio-frequency (RF) wireless signals and may include the transceiver circuit 1100 of FIG. 11. The wireless transceiver 1296 may facilitate communication over any suitable type of wireless network, such as a wireless local area network (LAN) (WLAN), a peer to peer (P2P) network, a mesh network, a cellular network, a wireless wide area network (WWAN), a navigational network (e.g., the Global Positioning System (GPS) of North America or another Global Navigation Satellite System (GNSS)), and/or a wireless personal area network (WPAN).

The various operations of methods described above may be performed by any suitable means capable of performing the corresponding functions. The means may include various hardware and/or software component(s) and/or module(s), including, but not limited to a circuit, an application-specific integrated circuit (ASIC), or processor.

By way of aspect, an element, or any portion of an element, or any combination of elements described herein may be implemented as a “processing system” that includes one or more processors. Aspects of processors include microprocessors, microcontrollers, graphics processing units (GPUs), central processing units (CPUs), application processors, digital signal processors (DSPs), reduced instruction set computing (RISC) processors, systems on a chip (SoC), baseband processors, field programmable gate arrays (FPGAs), programmable logic devices (PLDs), state machines, gated logic, discrete hardware circuits, and other suitable hardware configured to perform the various functionality described throughout the disclosure. One or more processors in the processing system may execute software. Software shall be construed broadly to mean instructions, instruction sets, code, code segments, program code, programs, subprograms, software components, applications, software applications, software packages, routines, subroutines, objects, executables, threads of execution, procedures, functions, etc., whether referred to as software, firmware, middleware, microcode, hardware description language, or otherwise.

Accordingly, in one or more aspect embodiments, the functions or circuitry blocks described may be implemented in hardware, software, or any combination thereof. If implemented in software, the functions may be stored on or encoded as one or more instructions or code on a computer-readable medium. Computer-readable media includes computer storage media. Storage media may be any available media that can be accessed by a computer. By way of aspect, and not limitation, such computer-readable media can include a random-access memory (RAM), a read-only memory (ROM), an electrically erasable programmable ROM (EEPROM), optical disk storage, magnetic disk storage, other magnetic storage devices, combinations of the aforementioned types of computer-readable media, or any other medium that can be used to store computer executable code in the form of instructions or data structures that can be accessed by a computer. In some aspects, components described with circuitry may be implemented by hardware, software, or any combination thereof.

The phrase “coupled to” and the term “coupled” refers to any component that is physically connected to another component either directly or indirectly, and/or any component that is in communication with another component (e.g., connected to the other component over a wired or wireless connection, and/or other suitable communication interface) either directly or indirectly.

Generally, where there are operations illustrated in figures, those operations may have corresponding counterpart means-plus-function components with similar numbering.

As used herein, the term “determining” encompasses a wide variety of actions. For some aspects, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes and variations may be made in the arrangement, operation and details of the methods and apparatus described above without departing from the scope of the claims.

Claim language or other language reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, A and B and C, or any duplicate information or data (e.g., A and A, B and B, C and C, A and A and B, and so on), or any other ordering, duplication, or combination of A, B, and C. The language “at least one of” a set and/or “one or more” of a set does not limit the set to the items listed in the set. For example, claim language reciting “at least one of A and B” or “at least one of A or B” may mean A, B, or A and B, and may additionally include items not listed in the set of A and B. The phrases “at least one” and “one or more” are used interchangeably herein.

Claim language or other language reciting “at least one processor configured to,” “at least one processor being configured to,” “one or more processors configured to,” “one or more processors being configured to,” or the like indicates that one processor or multiple processors (in any combination) can perform the associated operation(s). For example, claim language reciting “at least one processor configured to: X, Y, and Z” means a single processor can be used to perform operations X, Y, and Z; or that multiple processors are each tasked with a certain subset of operations X, Y, and Z such that together the multiple processors perform X, Y, and Z; or that a group of multiple processors work together to perform operations X, Y, and Z. In another example, claim language reciting “at least one processor configured to: X, Y, and Z” can mean that any single processor may only perform at least a subset of operations X, Y, and Z.

Where reference is made to one or more elements performing functions (e.g., steps of a method), one element may perform all functions, or more than one element may collectively perform the functions. When more than one element collectively performs the functions, each function need not be performed by each of those elements (e.g., different functions may be performed by different elements) and/or each function need not be performed in whole by only one element (e.g., different elements may perform different sub-functions of a function). Similarly, where reference is made to one or more elements configured to cause another element (e.g., an apparatus) to perform functions, one element may be configured to cause the other element to perform all functions, or more than one element may collectively be configured to cause the other element to perform the functions.

Where reference is made to an entity (e.g., any entity or device described herein) performing functions or being configured to perform functions (e.g., steps of a method), the entity may be configured to cause one or more elements (individually or collectively) to perform the functions. The one or more components of the entity may include at least one memory, at least one processor, at least one communication interface, another component configured to perform one or more (or all) of the functions, and/or any combination thereof. Where reference to the entity performing functions, the entity may be configured to cause one component to perform all functions, or to cause more than one component to collectively perform the functions. When the entity is configured to cause more than one component to collectively perform the functions, each function need not be performed by each of those components (e.g., different functions may be performed by different components) and/or each function need not be performed in whole by only one component (e.g., different components may perform different sub-functions of a function).

The following is a set of non-limiting aspects in accordance with the details provided herein:

Aspect 1. An device comprising: a substrate layer; a trap rich layer disposed on the substrate layer, the trap rich layer having a thickness less than or equal to 200 nanometers (nm); a dielectric layer disposed on the trap rich layer; a piezoelectric layer disposed on the dielectric layer; and an interdigital transducer formed in a metal layer disposed on the piezoelectric layer.

Aspect 2. The device of Aspect 1, wherein the thickness of the trap rich layer is greater than or equal to 10 nm.

Aspect 3. The device of any of Aspects 1 to 2, wherein the trap rich layer comprises Aluminum Nitride.

Aspect 4. The device of any of Aspects 1 to 2, wherein the trap rich layer comprises Si3N4.

Aspect 5. The device of any of Aspects 1 to 2, wherein the trap rich layer comprises Al₂O₃.

Aspect 6. The device of any of Aspects 1 to 5, wherein the dielectric layer comprises SiO2.

Aspect 7. The device of any of Aspects 1 to 6, further comprising a SiON layer disposed on the dielectric layer.

Aspect 8. The device of any of Aspects 1 to 7, wherein the substrate layer comprises polysilicon.

Aspect 9. The device of any of Aspects 1 to 7, wherein the substrate layer comprises a low cost high resistance silicon.

Aspect 10. The device of any of Aspects 1 to 9, wherein the thickness of the trap rich layer is selected to reduce out-of-band spurious modes while limiting the thickness of the trap rich layer.

Aspect 11. The device of any of Aspects 1 to 10, wherein the interdigital transducer comprises: a first busbar; a second busbar; and a first plurality of electrode fingers extending from the first busbar toward the second busbar and a second plurality of electrode fingers extending from the second busbar toward the first busbar in an interdigitated configuration with the first plurality of electrode fingers.

Aspect 12. An device comprising: a resonator configured for resonance associated with a resonance wavelength, the resonator comprising: a conductive substrate layer; a trap rich layer disposed on the conductive substrate layer, the trap rich layer having a thickness less than or equal to 0.125 times the resonance wavelength; a dielectric layer disposed on the trap rich layer; a piezoelectric layer formed on the dielectric layer; and an interdigital transducer formed in a metal layer disposed on the piezoelectric layer.

Aspect 13. The device of Aspect 12, wherein the thickness of the trap rich layer is greater than or equal to 10 nm.

Aspect 14. The device of any of Aspects 12 to 13, wherein the trap rich layer comprises Aluminum Nitride.

Aspect 15. The device of any of Aspects 12 to 13, wherein the trap rich layer comprises Si3N4.

Aspect 16. The device of any of Aspects 12 to 13, wherein the trap rich layer comprises Al₂O₃.

Aspect 17. The device of any of Aspects 12 to 16, wherein the dielectric layer comprises SiO2.

Aspect 18. The device of any of Aspects 12 to 17, further comprising a SiON layer disposed on the dielectric layer.

Aspect 19. The device of any of Aspects 12 to 18, wherein the conductive substrate layer comprises polysilicon.

Aspect 20. The device of any of Aspects 12 to 18, wherein the conductive substrate layer comprises a low cost high resistance silicon.

Aspect 21. The device of any of Aspects 12 to 20, wherein the thickness of the trap rich layer is selected to reduce out-of-band spurious modes while limiting the thickness of the trap rich layer.

Aspect 22. The device of any of Aspects 12 to 21, the interdigital transducer comprises: a first busbar; a second busbar; and a first plurality of electrode fingers extending from the first busbar toward the second busbar and a second plurality of electrode fingers extending from the second busbar toward the first busbar in an interdigitated configuration with the first plurality of electrode fingers.

Aspect 24. A method comprising: depositing a trap rich layer on a high resistance silicon substrate, wherein the trap rich layer is deposited to a thickness of less than 200 nanometers (nm); forming a dielectric layer on the trap rich layer; forming a piezoelectric layer on the dielectric layer; and forming an interdigital transducer on the piezoelectric layer.

Aspect 25. The method of Aspect 24, wherein the thickness of the trap rich layer is greater than or equal to 10 nm.

Aspect 26. The method of any of Aspects 24 to 25, wherein the trap rich layer comprises Aluminum Nitride.

Aspect 27. The method of any of Aspects 24 to 25, wherein the trap rich layer comprises Si3N4.

Aspect 28. The method of any of Aspects 24 to 25, wherein the trap rich layer comprises Al₂O₃.

Aspect 29. The method of any of Aspects 24 to 28, wherein the dielectric layer comprises SiO2.

Aspect 30. The method of any of Aspects 24 to 29, further comprising: forming a SiON layer disposed on the dielectric layer.

Aspect 31. The method of any of Aspects 24 to 30, further comprising forming the trap rich layer on a conductive substrate layer.

Aspect 32. The method of any of Aspects 24 to 31, wherein the conductive substrate layer comprises a low cost high resistance silicon.

Aspect 33. The method of any of Aspects 24 to 32, wherein the thickness of the trap rich layer is selected to reduce out-of-band spurious modes while limiting the thickness of the trap rich layer.

Aspect 34. The method of any of Aspects 24 to 33, wherein the interdigital transducer comprises: a first busbar; a second busbar; and a first plurality of electrode fingers extending from the first busbar toward the second busbar and a second plurality of electrode fingers extending from the second busbar toward the first busbar in an interdigitated configuration with the first plurality of electrode fingers.

Aspect 35. An electroacoustic resonator comprising: a substrate layer; a trap rich layer disposed on the substrate layer, the trap rich layer having a thickness less than or equal to 200 nanometers (nm); and a dielectric layer disposed on the trap rich layer.

Aspect 36. The electroacoustic resonator of Aspect 35, wherein the thickness of the trap rich layer is greater than or equal to 10 nm.

Aspect 37. The electroacoustic resonator of any of Aspects 35 to 36, wherein the trap rich layer comprises Aluminum Nitride.

Aspect 38. The electroacoustic resonator of any of Aspects 35 to 36, wherein the trap rich layer comprises Si3N4.

Aspect 39. The electroacoustic resonator of any of Aspects 35 to 36, wherein the trap rich layer comprises Al₂O₃.

Aspect 40. The electroacoustic resonator of any of Aspects 35 to 39, wherein the dielectric layer comprises SiO2.

Aspect 41. The electroacoustic resonator of any of Aspects 35 to 40, further comprising a SiON layer disposed on the dielectric layer.

Aspect 42. The electroacoustic resonator of any of Aspects 35 to 41, wherein the thickness of the trap rich layer is selected to reduce out-of-band spurious modes while limiting the thickness of the trap rich layer.

Aspect 43. The electroacoustic resonator of any of Aspects 35 to 42, further comprising: a piezoelectric layer disposed on the dielectric layer; and a metal layer disposed on the piezoelectric layer, the metal layer comprising an interdigital transducer comprising: a first busbar; a second busbar; and a first plurality of electrode fingers extending from the first busbar toward the second busbar and a second plurality of electrode fingers extending from the second busbar toward the first busbar in an interdigitated configuration with the first plurality of electrode fingers.

What is claimed is:

1. An device comprising:
a substrate layer;
a trap rich layer disposed on the substrate layer, the trap rich layer having a thickness less than or equal to 200 nanometers (nm);
a dielectric layer disposed on the trap rich layer;
a piezoelectric layer disposed on the dielectric layer; and
an interdigital transducer formed in a metal layer disposed on the piezoelectric layer.

2. The device of claim 1, wherein the thickness of the trap rich layer is greater than or equal to 10 nm.

3. The device of claim 1, wherein the trap rich layer comprises Aluminum Nitride.

4. The device of claim 1, wherein the trap rich layer comprises Si3N4.

5. The device of claim 1, wherein the trap rich layer comprises Al2O3.

6. The device of claim 1, wherein the dielectric layer comprises SiO2.

7. The device of claim 1, further comprising a SiON layer disposed on the dielectric layer.

8. The device of claim 1, wherein the substrate layer comprises polysilicon.

9. The device of claim 1, wherein the substrate layer comprises a low cost high resistance silicon.

10. The device of claim 1, wherein the thickness of the trap rich layer is selected to reduce out-of-band spurious modes while limiting the thickness of the trap rich layer.

11. The device of claim 1, wherein the interdigital transducer comprises:
a first busbar;
a second busbar; and
a first plurality of electrode fingers extending from the first busbar toward the second busbar and a second plurality of electrode fingers extending from the second busbar toward the first busbar in an interdigitated configuration with the first plurality of electrode fingers.

12. An device comprising:
a resonator configured for resonance associated with a resonance wavelength, the resonator comprising:
a conductive substrate layer;
a trap rich layer disposed on the conductive substrate layer, the trap rich layer having a thickness less than or equal to 0.125 times the resonance wavelength;
a dielectric layer disposed on the trap rich layer;
a piezoelectric layer formed on the dielectric layer; and
an interdigital transducer formed in a metal layer disposed on the piezoelectric layer.

13. The device of claim 12, wherein the thickness of the trap rich layer is greater than or equal to 10 nm.

14. The device of claim 12, wherein the trap rich layer comprises Aluminum Nitride.

15. The device of claim 12, wherein the trap rich layer comprises Si3N4.

16. The device of claim 12, wherein the trap rich layer comprises Al2O3.

17. A method comprising:
depositing a trap rich layer on a high resistance silicon substrate, wherein the trap rich layer is deposited to a thickness of less than or equal to 200 nanometers (nm);
forming a dielectric layer on the trap rich layer;
forming a piezoelectric layer on the dielectric layer; and
forming an interdigital transducer on the piezoelectric layer.

18. The method of claim 17, wherein the thickness of the trap rich layer is greater than or equal to 10 nm.

19. The method of claim 17, wherein the trap rich layer comprises Aluminum Nitride, Si3N4, or Al2O3.

20. The method of claim 17, further comprising:
forming a SiON layer disposed on the dielectric layer; and
forming the trap rich layer on a conductive substrate layer, the conductive substrate layer comprises a low cost high resistance silicon.
